(19) United States
(12) Patent Application Publication
(10) Pub. No.: US 2019/0371716 A1
(43) Pub. Date: Dec. 5, 2019

(54) METHOD FOR FABRICATING AN INTEGRATED CIRCUIT CHIP AND INTEGRATED CIRCUIT CHIP

(71) Applicant: COMMISSARIAT À L'ENERGIE ATOMIQUE ET AUX ENERGIES ALTERNATIVES, Paris (FR)

(72) Inventors: Mathilde CARTIER, Grenoble (FR); Emmanuel ARÈNE, Biviers (FR); Jean BRUN, Champagnier (FR); Pierre DESCOURS, Coublevie (FR); Julie HAGUET, Grenoble (FR)

(73) Assignee: COMMISSARIAT À L'ENERGIE ATOMIQUE ET AUX ENERGIES ALTERNATIVES, Paris (FR)

(21) Appl. No.: 16/480,243

(22) PCT Filed: Jan. 23, 2018
(86) PCT No.: PCT/FR2018/050157

§ 371 Date: Jul. 23, 2019

(30) Foreign Application Priority Data
Jan. 23, 2017 (FR) 1750546

(51) Int. Cl. H01L 23/498; H01L 23/495; H01L 25/065; H01L 23/00

(52) U.S. Cl. CPC H01L 23/49811; H01L 23/49575; H01L 2224/83801; H01L 24/83; H01L 24/85; H01L 25/0657

(57) ABSTRACT

A fabrication method of the device includes provision of a first stack including: a first substrate including at least one main surface provided with at least a first electric contact area, a second substrate provided with a salient spacer. The first substrate is assembled with the second substrate so as to define at least a first lateral groove including the first electric contact area, the first lateral groove being bounded by the first substrate, the second substrate and the spacer includes at least a first protuberance arranged to form a stop and to limit movement of the spacer relatively to the first substrate in at least a first direction passing via the first lateral groove and the spacer and a second direction parallel the longitudinal axis of the first groove and perpendicular to the first direction.

### BACKGROUND OF THE INVENTION

The invention relates to a method for fabricating an electronic device and in particular an integrated circuit chip.

The invention also relates to an electronic device.

### STATE OF THE ART

A large number of documents describe fabrication of integrated circuit chips that are electrically and mechanically connected to electrically conducting wires.

U.S. Pat. No. 8,723,312 describes different chip architectures. These chips comprise a first substrate separated from a second substrate by a spacer. The spacer presents a smaller width than the first and second substrates so as to define one or two lateral grooves that are used for performing embedding of an electrically conducting wire.

The document WO2008/025889 describes a microelectronic chip comprising two parallel main surfaces and opposite lateral surfaces. At least one of the lateral surfaces comprises a groove provided with an electric connection part forming a housing for a wire element having an axis parallel to the longitudinal axis of the groove.

In this way, the integrated circuit that is present in the first substrate is placed in electric contact with an external component by means of the electrically conducting wire that is inserted in the groove.

U.S. Pat. No. 8,723,312 also describes a method for inserting a wire element in the groove.

For correct operation of the integrated circuit, the signals output from or input to the integrated circuit have to transit via the electrically conducting wire. The electric connection between the electrically conducting wire and the integrated circuit therefore stands out as a crucial point for fabrication of the chips.

It is also apparent that substantial constraints exist as regards the dimensions of the chip, in particular as regards the dimensions of the grooves, in order to be able to easily embed the electrically conducting wires in lasting manner.

U.S. Pat. No. 7,723,854 proposes fabricating an electric connection using capillarity phenomena. Two metallic solder bumps are formed on a substrate and an object is placed between the two solder bumps, the two solder bumps being in contact with the object. In an alternative embodiment, the two solder bumps are placed on each side of the object and at the end of the object. The assembly is then placed on the substrate so that the solder bumps come into contact with the substrate.

An anneal is then performed to melt the metallic solder bumps and securedly fix the object with the substrate.

### OBJECT OF THE INVENTION

One object of the invention is to provide a method for fabricating an electronic device that is easy to implement and that enables a more efficient device to be achieved.

The method for fabricating the electronic device comprises:

providing a first stack comprising:
a first substrate comprising at least one main surface provided with at least a first electric contact area,
a second substrate provided with a salient spacer,

assembling the first substrate with the second substrate so as to define at least a first lateral groove comprising the first electric contact area, the first lateral groove being bounded by the first substrate, the second substrate and the spacer.

The method is remarkable in that, when assembly of the second substrate with the first substrate is performed, the first substrate comprises at least a first protuberance arranged to form a stop and to limit movement of the spacer relatively to the first substrate in at least a first direction passing via the first lateral groove and the spacer and a second direction parallel to the longitudinal axis of the first groove and perpendicular to the first direction.

In one development, when assembly of the second substrate with the first substrate is performed, the first substrate further comprises a second electric contact area on said at least one main surface, the first electric contact area being distinct from the second electric contact area, the second substrate being configured to define at least a second lateral groove comprising the second electric contact area, with the first substrate, the second lateral groove being separated from the first lateral groove by the spacer.

In advantageous manner, the spacer is fixed to the second substrate before assembly of the second substrate with the first substrate is performed.

In an alternative embodiment, the method comprises an additional step of fixing of the second substrate with the first substrate after the second substrate has been assembled with the first substrate.

Advantageously, the additional step of fixing is performed by bonding, melting of a fusible material, molecular sealing or anodic sealing of the spacer with the first substrate.

Preferentially, the additional step of fixing is performed by applying a pressure stress between the first substrate and the second substrate.

It is advantageous to provide for the additional step of fixing to be performed by means of a heat treatment.

In an advantageous embodiment, said at least a first protuberance is electrically conducting and connected to the first electric contact area, the at least a first protuberance being configured to prevent movement of the spacer at least in the first direction.

In one development, at least the first protuberance defines at least one stop in the first direction and the spacer comprises a first side wall defining a first salient area salient in the first direction, the stop collaborating with the first salient area to prevent movement of the spacer in the second direction.

In a particular embodiment, the first substrate comprises at least a second electrically conducting protuberance connected to the second electric contact area, the second protuberance being configured to prevent movement of the spacer at least in the first direction.

It is advantageous to provide for the second protuberance to define at least one stop in the first direction and for the spacer to comprise a second side wall opposite the first side wall defining a second salient area in the first direction, the second protuberance collaborating with the second salient area to prevent movement of the spacer in the second direction, the first and second protuberances preventing movement of the spacer in the first direction and in the second direction in two opposite directions.

Preferentially, the spacer comprises at least a first portion and a second portion, the first portion having a smaller width than the second portion, the width being defined in the first direction, the first and second portions being arranged consecutively in the second direction to define the first salient area.

In advantageous manner, the spacer comprises at least a third portion having a larger width than the width of the first portion, the third portion being separated from the second portion by the first portion to define the second salient area.

In another development, the first and second salient areas are separated by the first portion of the spacer.

Preferentially, said at least a first protuberance is made from a brazing material.

In a preferential embodiment, the method for fabricating comprises insertion of at least a first electrically conducting wire in the first lateral groove and an annealing step configured to at least partially eliminate the stop of the first protuberance by transforming the brazing material into a liquid material that at least partially covers the first electrically conducting wire by capillarity. It is a further object of the invention to provide an electronic device that presents a better resistance in time than devices of the prior art.

The electronic device comprises:

a first substrate comprising at least one main surface provided with at least a first electric contact area,

a second substrate comprising a spacer, the spacer separating the first substrate and the second substrate to define at least a first lateral groove comprising the first electric contact area.

The device is remarkable in that the first substrate comprises at least a first protuberance arranged to form a stop and to limit movement of the spacer relatively to the first substrate in a first direction passing through the first lateral groove and the spacer and in a second direction perpendicular to the first direction, the second direction being parallel to the longitudinal axis of the first lateral groove.

### BRIEF DESCRIPTION OF THE DRAWINGS

Other advantages and features will become more clearly apparent from the following description of particular embodiments of the invention given for non-restrictive example purposes only and represented in the appended drawings, in which:

FIG. 1 represents a first embodiment of an integrated circuit chip, in schematic manner, in cross-section,

FIGS. 2, 3 and 4 represent three alternative embodiments of a spacer placed on a first substrate and separating two wire elements, in schematic manner, in top view,

FIG. 5 represents a second embodiment of an integrated circuit chip, in schematic manner, in cross-section,

FIG. 6 represents another alternative embodiment of a spacer placed on a first substrate and separating two wire elements, in schematic manner, in top view.

### DETAILED DESCRIPTION

As illustrated in FIG. 1, the electronic device is a chip or integrated circuit chip that comprises a first substrate 1 and a second substrate 2 that are separated by a spacer 4. The chip comprises two opposite external main surfaces 1a and 2a. First external main surface 1a is formed by a first surface of first substrate 1.

Second external main surface 2a is formed by a first surface of second substrate 2. Preferentially, the two opposite external main surfaces 1a and 2a are parallel. Preferentially, the chip comprises two main surfaces 1a and 2a connected to one another by lateral surfaces. At least one groove 3a/3b is present in one of the lateral surfaces. In the illustrated embodiment, two grooves 3a and 3b are formed. In the illustrated embodiment, the two lateral grooves 3a and 3b are separated by a spacer 4.

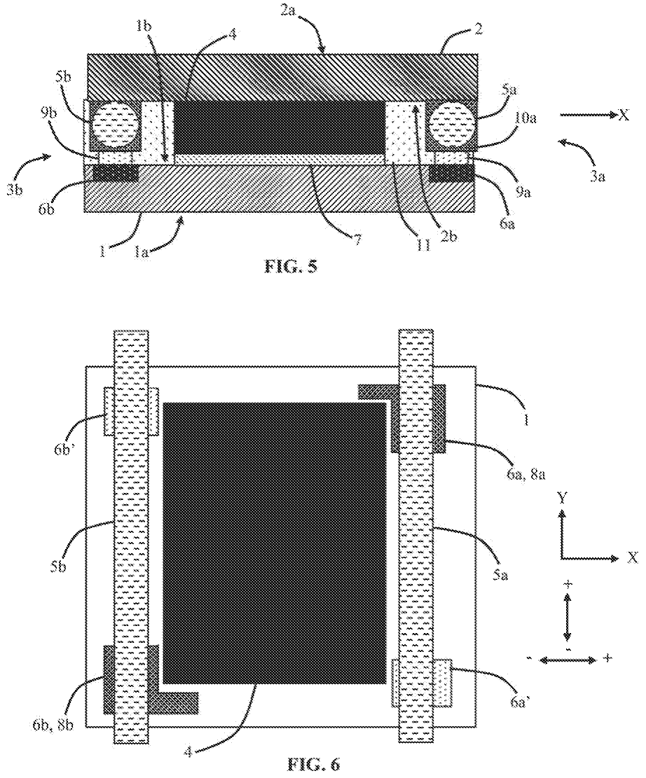

In the embodiments illustrated in FIGS. 1 to 6, the general shape of the chip is a parallelepiped, and the two external main surfaces can then be of substantially equal dimensions and are connected by four lateral surfaces.

Other chip shapes are naturally possible. It is possible for example to have a first substrate 1 and/or a second substrate 2 presenting a convex external main surface. Furthermore, a lateral surface can be the continuation of the main surface without any precise demarcation edges between the latter.

The chip is formed by providing a first substrate 1 and then associating thereto a second substrate 2 comprising a salient spacer 4. Spacer 4 separates first substrate 1 and second substrate 2. In a first embodiment, spacer 4 has been fixed with second substrate 2, for example by bonding. In an alternative embodiment, spacer 4 is formed in second substrate 2 by etching of second substrate 2. It is also possible to combine these two embodiments.

In a first embodiment, spacer 4 is brought into contact with first substrate 1 and a fixing step is then advantageously performed in order to fix spacer 4 on first substrate 1. The fixing step can be executed by applying a pressure between first substrate 1 and second substrate 2 and advantageously applying an anneal. In a particularly advantageous embodiment, fixing of spacer 4 with first substrate 1 is performed by bonding. In preferential manner, the fixing step is performed by bonding, melting of a fusible material, molecular sealing or anodic sealing of spacer 4 with first substrate 1.

In preferential manner, the fixing step is performed by means of an anneal. In a particular embodiment, fixing is performed by means of an anneal at a maximum temperature comprised between the glass transition temperature and the polymerisation temperature of the adhesive used to bond spacer 4 with first substrate 1. For example purposes, the adhesive is a glue marketed by Brewer Science Inc. under the tradename HT1010.

Wire elements 5a, 5b are then inserted longitudinally respectively in grooves 3a, 3b. Wire elements 5a, 5b are preferably mechanically clamped in grooves 3a, 3b.

As an alternative, wire elements 5a, 5b are placed in the chip before the fixing step.

First substrate 1 comprises at least one functional block configured to perform at least one logic and/or analog function and possibly a mechanical function (cf. electric wire support, etc.). First substrate 1 also comprises at least a first electric contact area 6a. In the illustrated embodiment, first substrate 1 comprises a second electric contact area 6b. In advantageous manner, first substrate 1 comprises a silicon substrate or is constituted by a silicon substrate. In a particular embodiment, the first integrated circuit is configured to perform a radio frequency identification (RFID) function. In advantageous manner, the functional block is an integrated circuit configured to perform at least one logic and/or analog function. It is also possible for the functional block to perform a mechanical function and advantageously support of the electric wires.

First electric contact area 6a is distinct from second electric contact area 6b and these two areas are separated by a first distance. The two electric contact areas 6a and 6b are electrically connected to the integrated circuit formed in first substrate 1. If a single lateral groove 3a is defined, a single electric contact area 6a can be formed and connected to the integrated circuit.

The at least two electric contact areas 6a and 6b are formed on a second surface 1b of first substrate 1 opposite first surface 1a of first substrate 1. Second face 1b of first substrate 1 is directly facing second surface 2b of second substrate 2. Surfaces 1b and 2b are called internal main surfaces or simply main surfaces.

Second surface 1b of first substrate 1 is made from an electrically insulating or semi-insulating material and advantageously from a material forming a barrier against external pollutants, for example water. The two electric contact areas 6a and 6b are formed inside the insulating and barrier layer. In conventional manner, electric contact areas 6a and 6b present a small surface as they have to be integrated in first substrate 1 without hampering transit of the signals in the different interconnection levels. It is possible to use silicon as semi-insulating material.

The two electric contact areas 6a and 6b are formed on a peripheral area of first substrate 1 so as to be situated inside the two lateral grooves 3a and 3b of the chip. As a variant, more than two electric contact areas are present with for example additional contact areas 6a′ and 6b′.

Spacer 4 and second substrate 2 are secured to first substrate 1 to define lateral grooves 3a and 3b. Lateral groove 3a is defined by means of first substrate 1, second substrate 2 and spacer 4. The same can be the case for second groove 3b.

In an advantageous embodiment, first substrate 1 and second substrate 2 are configured to form a plurality of chips. First substrate 1 comprises a plurality of identical or different integrated circuits that are advantageously repeated with a first repetition pitch in the first direction X and that are advantageously repeated with a second repetition pitch in the second direction Y.

Second substrate 2 is placed on first substrate 1 so as to form the plurality of chips that comprise lateral grooves. Once the two substrates have been placed in contact and secured to one another, a dicing step can be performed so as to dice first substrate 1, second substrate 2 and possibly spacer 4 thereby defining a plurality of chips. The chips can then be separated from one another.

In a first particular case, first substrate 1 comprises predefined weakening lines in order to define the dimensions of the different chips and to facilitate subsequent dicing. The same is the case for second substrate 2. It is particularly advantageous to align first substrate 1 correctly with the assembly formed by spacer 4 and second substrate 2 in order to align the predefined weakening lines and facilitate dicing of the chips.

Spacer 4 presents a smaller width than the width of first substrate 1 and than the width of second substrate 2 so as to define two lateral grooves or at least one lateral groove. It is particularly advantageous to provide for the length of spacer 4 to be shorter than the first length of first substrate 1 and than the second length of second substrate 2 to facilitate dicing of the chips. Second substrate 2 then comprises a plurality of distinct spacers 4. Dicing of second substrate 2 is preferentially performed in the areas devoid of spacers 4.

In a second particular case, first substrate 1 and/or second substrate 2 are devoid of predefined weakening lines. The chips are diced by any suitable technique, for example by means of a dicing saw or a laser beam. In this particular case, first substrate 1 and second substrate 2 present identical dimensions in the first direction and in the second direction.

As indicated in the above, it is necessary to master the alignment of first substrate 1 with respect to spacer 4 and to second substrate 2. This alignment has to be controlled when contact is made with first substrate 1 and also has to be controlled when the fixing phase of first substrate 1 with spacer 4 is executed.

Depending on the embodiments, spacer 4 and second substrate 2 are made from different materials or spacer 4 and second substrate 2 are made from the same materials. In advantageous manner, second substrate 2 can comprise or be constituted by a silicon substrate. As an alternative, second substrate 2 can be made from an electrically insulating material or from an electrically conducting material covered by an electrically insulating layer.

In one embodiment, second substrate 2 is an active element, i.e. it comprises an electronic component, for example a battery. Second substrate 2 can be configured to supply power to first substrate 1. As an alternative, second substrate 2 is devoid of any electronic component.

In one embodiment, spacer 4 and second substrate 2 are formed separately and are subsequently assembled to one another. Spacer 4 can be fixed on second substrate 2 by any known means. In an alternative embodiment, spacer 4 is formed in second substrate 2 by etching. It is advantageous to fabricate second substrate 2 and spacer 4 from a silicon substrate that has undergone a deep etching step in order to define spacer 4 or several spacers.

Spacer 4 separates first substrate 1 and second substrate 2 and defines a first lateral groove 3a and advantageously a second lateral groove 3b with the latter. Each lateral groove comprises two opposite surfaces respectively formed by first substrate 1 and second substrate 2 and a bottom formed by spacer 4. The two lateral grooves 3a/3b are in this way separated by spacer 4. Each groove 3a/3b is open at both ends.

First electric contact area 6a is located on the first lateral surface of first lateral groove 3a. Second electric contact area 6b is located on the first lateral surface of second lateral groove 3b.

In a particular embodiment, first lateral groove 3a and/or second lateral groove 3b have an additional electric contact area 6a′/6b′. This additional electric contact area makes it possible to transmit and/or receive different signals from the first or second electric contact area present in groove 3a/3b.

The chip possesses or is designed to accommodate first and second electrically conducting wires 5a/5b also called first and second wire elements. First and second electrically conducting wires 5a/5b are designed to come into electric contact respectively with first electric contact area 6a and second electric contact area 6b and possibly with areas 6a′ and 6b′.

Each wire element 5a/5b presents a longitudinal axis that is parallel or substantially parallel to the longitudinal axis of groove 3a/3b, i.e. parallel to direction Y. Each wire element 5a/5b is secured to first substrate 1 by welding with addition of material, by bonding, and/or by embedding. Embedding in groove 3a/3b requires correct dimensioning of wire element 5a/5b and groove 3a/3b. The mechanical strength by embedding may be insufficient and in general requires a reinforcement phase by addition of an adhesive and/or metal.

Electrically conducting wires 5a/5b can present any cross-section. Depending on the embodiments, first and second electrically conducting wires 5a/5b are single-strand or multi-strand conducting wires. It is therefore possible to have a chip comprising two single-strand conducting wires or two multi-strand conducting wires or a mixture of these two technologies. A multi-strand conducting wire comprises several conducting wires that are electrically dissociated and convey different electric signals. As an alternative, the multi-strand conducting wire comprises several conducting wires that are electrically connected to one another and convey the same electric signal. A multi-strand conducting wire can for example be in the form of a strand of several electrically conducting wires. It is particularly advantageous to use a multi-strand conducting wire in association with an adhesive as the adhesive material used to secure the electrically conducting wire with first substrate 1 becomes impregnated in the gaps of the wires thereby enhancing the quality of adhesion. The adhesive can be of any type, for example formed by a brazing material.

When the chip is an RFID chip, first and/or second electrically conducting wires 5a/5b are advantageously configured to form communication antennas.

First and second electrically conducting wires 5a/5b are advantageously configured to be embedded in first groove 3a and in second groove 3b, i.e. first substrate 1 and second substrate 2 both press on electrically conducting wires 5a/5b so that the latter remain inside the lateral groove. In this way, the risks of electrically conducting wires 5a/5b being separated from the chip are reduced. First and second electrically conducting wires 5a/5b can be compressed by means of first and second substrates 1 and 2. As an alternative, first and second electrically conducting wires 5a/5b are not compressed by first and second substrates 1 and 2.

The height of spacer 4 and the cross-section of electrically conducting wires 5a/5b are advantageously configured to ensure that the electrically conducting wires are compressed between the two substrates.

In advantageous manner, a fixing layer 7 is placed between spacer 4 and first substrate 1 so as to secure spacer 4 with first substrate 1. Fixing layer 7 can be placed on first substrate 1 and/or on spacer 4. In general manner, fixing of spacer 4 with first substrate 1 is performed by any known technique, for example by bonding, brazing, or welding.

First substrate 1 can be of any shape. However, it is advantageous to provide a first substrate 1 that presents a square or rectangular cross-section. First substrate 1 presents a first width measured in a first direction X and a first length measured in a second direction Y. First direction X is perpendicular to second direction Y.

Second substrate 2 can be of any shape. There again, it is advantageous to provide a second substrate 2 that presents a square or rectangular cross-section. Second substrate 2 presents a second width measured in first direction X and a second length measured in second direction Y.

In a preferential embodiment, the first length is equal to the second length and/or the first width is equal to the second width.

It is particularly advantageous to provide for the shape of first substrate 1 to be identical to the shape of second substrate 2 thereby enhancing the ruggedness of the chip when the latter is in use, in particular by reducing the risk of separation of first substrate 1 from second substrate 2.

In order to be integrated in a very large number of applications, the chips present small dimensions which complicates their fabrication method by increasing the criticality of the alignment constraints between first substrate 1 and the assembly formed by spacer 4 and second substrate 2.

As indicated in the foregoing, the assembly formed by spacer 4 and second substrate 2 is configured to define one or two lateral grooves with first substrate 1.

A first constraint therefore exists in first direction X so that the two lateral grooves present sufficient dimensions to accept and secure each of the two electrically conducting wires 5a/5b.

By definition, as spacer 4 is less wide than second substrate 2, it is not possible to see the exact position of spacer 4 when placing the latter. It is also complicated to estimate the position of spacer 4 relatively to the position of second substrate 2 as their respective positions may change according to the unknowns of the fabrication methods (adhesion of spacer 4 on second substrate 2, etching of spacer 4 in second substrate 2 , etc.).

The inventors observed that the alignment constraints are present in first direction X. This constraint in first direction X enables spacer 4 to be centred with respect to the two electric contact areas of first substrate 1 that are situated on each side of spacer 4 after the assembly step.

During the fabrication method of the chip, the assembly formed by spacer 4 and second substrate 2 is placed in contact with first substrate 1. A first alignment is performed in directions X and Y so as to judiciously place spacer 4 relatively to first substrate 1 thereby defining the two lateral grooves and ensuring that first substrate 1 is correctly placed facing second substrate 2. This placing of spacer 4 with respect to first substrate 1 is called assembly step.

The assembly step enables at least first lateral groove 3a comprising first contact area 6a to be defined.

Following the assembly step, a fixing step is performed so as to secure first substrate 1 with spacer 4 and therefore first substrate 1 with second substrate 2. When the two substrates are secured to one another, a pressure stress is applied on first substrate 1 and on second substrate 2 resulting in a possible movement of first substrate 1 with respect to second substrate 2 by sliding on surface 1 b of first substrate 1. This movement is linked for example to fixing layer 7 situated between first substrate 1 and spacer 4. Just before adhesion, layer 7 is transformed and generally liquefies threreby encouraging sliding between spacer 4 and first substrate 1. When sliding takes place, spacer 4 moves resulting in a modification of the dimensions of the lateral grooves. The first alignment is impaired or even lost.

In order to ensure correct alignment during the assembly step and to prevent movement of spacer 4 when spacer 4 is secured with first substrate 1, blocking means are placed on first substrate 1. The blocking means are advantageously formed by at least a first protuberance 8a salient with respect to second surface 1 b of first substrate 1 so as to come into contact with spacer 4 and prevent movement thereof at least in first direction X and advantageously in second direction Y. In this way, the first alignment made when spacer 4 is brought into contact with first substrate 1 is partially kept when securing/fixing of spacer 4 to first substrate 1 is performed.

It is particularly advantageous to use at least a first protuberance 8a that forms a stop limiting movement of spacer 4 in direction X and advantageously in direction Y. First protuberance 8a can be of any shape. In advantageous manner, it is advantageous to use a plurality of different protuberances so as to form a plurality of stops limiting movement of spacer 4 in directions X and/or Y.

However, it is also possible to use a single protuberance arranged to limit movement of spacer 4 in directions X and/or Y. The protuberance can for example pass around the mechanical contact area between spacer 4 and first substrate 1. As an alternative, the protuberance can be C-shaped or L-shaped in order to limit movement of spacer 4 in directions X and Y and in one or two directions opposite to each direction.

As the chip has small dimensions, it is particularly advantageous to use first and second protuberances 8a and 8b that are respectively connected to first electric contact area 6a and second electric contact area 6b and that are configured to limit movement of spacer 4 in first direction X and in second direction Y. It is particularly advantageous to provide an electrically conducting protuberance forming at least a part of the electric contact area.

First and second protuberances 8a and 8b participate in fixing of first and second electrically conducting wires 5a and 5b against first substrate 1 and in improving the electric connection between electrically conducting wire 5a/5b and the contact area.

In this way, the plurality of protuberances formed on first substrate 1 comprises at least two protuberances electrically connected to the integrated circuit. First protuberance 8a enables first electrically conducting wire 5a to be blocked in first lateral groove 3a and first electrically conducting wire 5a to be connected with first electric contact area 6a. Second protuberance 8b enables second electrically conducting wire 5b to be blocked in second lateral groove 3b and second electrically conducting wire 5b to be connected with second electric contact area 6b.

First and second protuberances 8a and 8b are formed from an electrically conducting material that provides the electric contact between electrically conducting wire 5a/5b and the integrated circuit.

In advantageous manner, first protuberance 8a and/or second protuberance 8b comprise or are constituted by a brazing material that is configured to melt and to cover electrically conducting wire 5a/5b by capillarity in order to enhance the adhesion between the chip and electrically conducting wire 5a/5b.

In a preferential embodiment, first protuberance 8a is achieved by means of several electrically conducting materials. In the embodiment illustrated in FIG. 1, first and second salient areas 9a and 10a are superposed to form first protuberance 8a. A first electrically conducting material is covered by a second electrically conducting material. The first electrically conducting material has a melting temperature that is higher than the melting temperature of the second electrically conducting material by a value advantageously equal to 30° C. The second electrically conducting material is also called brazing material. In a particular embodiment, first protuberance 8a is formed by area 10a only. It is also possible to provide for first protuberance 8a and/or second protuberance 8b to be formed solely from brazing material.

In one embodiment, first protuberance 8a and second protuberance 8b are configured to prevent movement of spacer 4 in direction X in one way, i.e. the misalignment is limited in a single direction for example the +way or the - way. In another embodiment, first protuberance 8a and second protuberance 8b are configured to prevent movement of spacer 4 in direction X in both ways, i.e. the misalignment is limited in the + way and in the − way. First and second protuberances 8a and 8b are respectively placed in first groove 3a and in second groove 3b.

In a particularly advantageous embodiment, first protuberance 8a extends beyond first electric contact area 6a and second protuberance 8b extends beyond second electric contact area 6b. In preferential manner, second electrically conducting material 10a/10b is a brazing material and advantageously extends beyond the first electrically conducting material forming first salient area 9a/9b.

Each lateral groove 3a/3b advantageously comprises a protuberance that is salient from electric contact area 6a/6b and that limits movement of spacer 4 in first direction X. In case of sliding, the spacer 4 comes up against the stop formed by one of the protuberances which blocks it thereby enabling a lateral groove 3a/3b having a minimum depth to be kept. The width of spacer 4 defines the maximum depth of the other lateral groove.

The stop that is provided to limit the movement in direction Y ensures a minimum connection surface between spacer 4 and first substrate 1 and therefore a certain adhesive strength. This also makes it possible to limit the offset between the two substrates which could weaken the chip by facilitating flexural stresses on one end of the substrates.

During the fixing step, spacer 4 may shift slightly but it comes up against the stop formed by the blocking means in direction X and in direction Y thereby preventing an excessive modification of the dimensions of the lateral grooves both as far as its width or depth measured in direction X or as far as its length measured in direction Y are concerned.

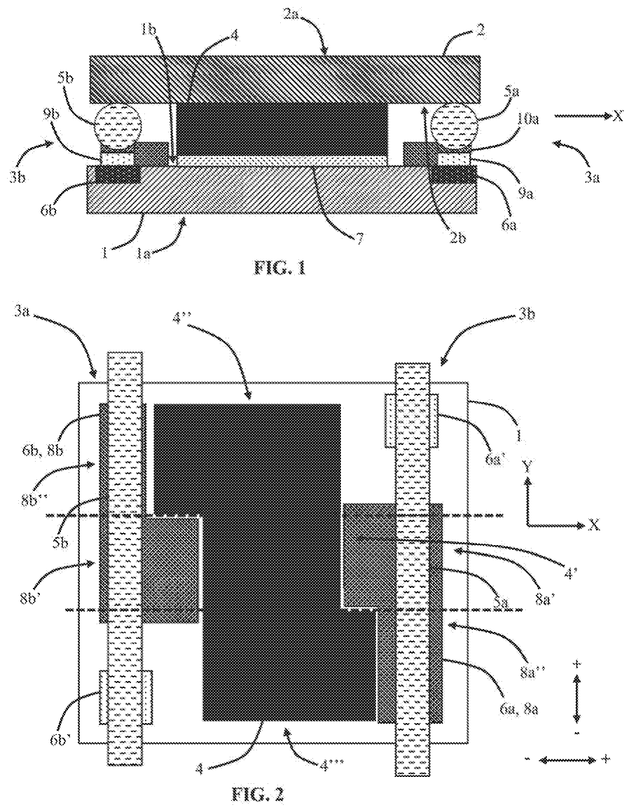

In a particular embodiment illustrated in FIGS. 2, 3 and 4, spacer 4 comprises a first side wall defining a first salient area in direction X, i.e. in a direction successively passing via first wire element 5a, spacer 4 and second wire element 5b. First protuberance 8a collaborates with the first salient area to prevent movement of spacer 4 in second direction Y and in at least one way of movement. Blocking is achieved when first protuberance 8a comes into contact with the salient area of spacer 4. This salient area comes up against the stop formed by an area of the first protuberance that is advantageously solely formed by the brazing material.

If the stop limiting movement of spacer 4 in direction Y is formed solely by brazing material, it is advantageous to perform fixing of spacer 4 with first substrate 1 before annealing the brazing material to transform it into a liquid material.

In advantageous manner, spacer 4 comprises a second side wall opposite the first side wall. This second side wall defines a second salient area in direction X, i.e. a direction successively passing via first wire element 5a, spacer 4 and second wire element 5b. Second protuberance 8b collaborates with the second salient area to prevent movement of spacer 4 in second direction Y. In advantageous manner, the two protuberances collaborate to clamp spacer 4 in two opposite ways. In this way, when spacer 4 moves in a first way, the first salient area comes up against the stop formed by first protuberance 8a. When spacer 4 moves in a second way, the second salient area comes up against the stop formed by second protuberance 8b. This second salient area comes up against the stop formed by an area of the second protuberance that is advantageously solely formed by the brazing material.

There again, the positions of first protuberance 8a, second protuberance 8b, first salient area and second salient area in direction Y enable the maximum misalignment allowed for spacer 4 to be defined.

In a particular embodiment, spacer 4 comprises at least a first portion 4′ and a second portion 4″ arranged consecutively in direction Y. First portion 4′ presents a smaller width than the width of second portion 4″. The width is defined in direction X, i.e. in a direction successively passing via first wire element 5a, spacer 4 and second wire element 5b. The first and second portions advantageously define the first salient area of the spacer.

In this particular case, it is also advantageous to provide for spacer 4 to comprise a third portion 4″′ separated from second portion 4″ by first portion 4′ in direction Y. Third portion 4″′ has a larger width than the width of first portion 4′. This embodiment is simple to implement. The first, second and third portions advantageously define the first and second salient areas of the spacer.

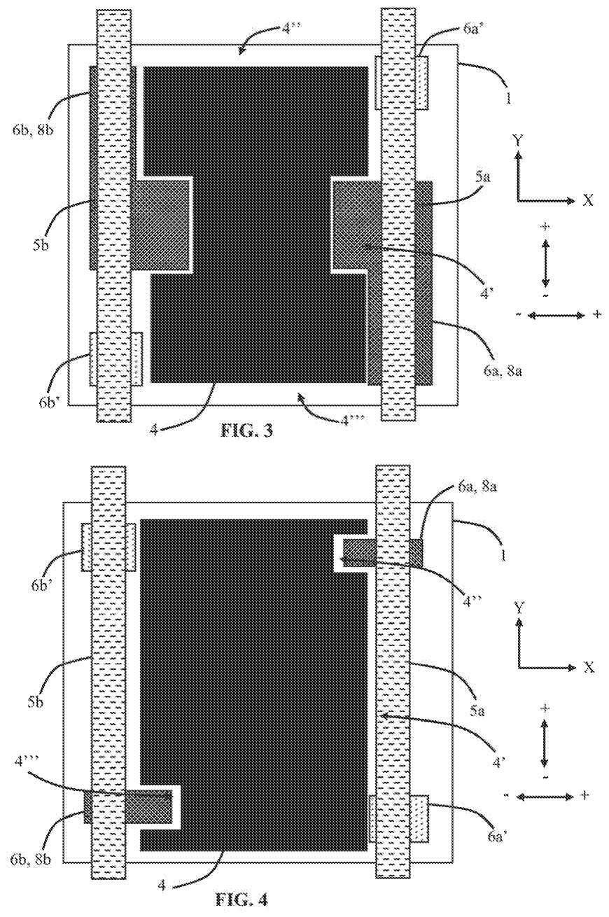

In the embodiment illustrated in FIG. 2, one of the side walls of first portion 4′ is in the continuation of one of the side walls of second portion 4″ and the other side wall of first portion 4′ is in the continuation of the other side wall of third portion 4″′. Each side wall therefore serves the purpose of preventing movement of spacer 4 in one direction. This embodiment is particularly simple to implement. As an alternative, it is also possible to provide for at least one of the side walls to prevent movement of spacer 4 in the two opposite ways (+ and −) as illustrated in FIGS. 3 and 4.

In a particular embodiment that is not represented, spacer 4 does not comprise a portion 4′.

It is also advantageous to provide for first protuberance 8a and second protuberance 8b to be facing first portion 4′ of spacer 4 in direction X to block spacer 4 as illustrated in FIGS. 2 and 3. It is also advantageous to provide for a direction parallel to direction X to pass via first protuberance 8a, first portion 4′ of spacer 4 and second protuberance 8b.

In a particular embodiment illustrated in FIG. 2, first protuberance 8a has a first portion 8a′ and a second portion 8a″ that are consecutive in direction Y. First portion 8a′ and second portion 8a″ define a salient area in direction X on the inner side wall of first protuberance 8a. The inner side wall is the side wall facing spacer 4. In the embodiment illustrated in FIG. 4, the two protuberances are offset in direction Y.

In another particular embodiment, second protuberance 8b also has a first portion 8b′ and a second portion 8b″ consecutive in direction Y. First portion 8b′ and second portion 8b″ define a salient area in direction X on the inner side wall of second protuberance 8b. The inner side wall is the side wall facing spacer 4. This embodiment is simple to implement.

First portion 8a′ of the first protuberance defines a salient area extending in the direction of the center of the chip, i.e. in the direction of spacer 4 when going from one end of the chip to the centre of the chip in direction X. The salient portion of spacer 4 consequently extends in the direction of first protuberance 8a″ in the opposite way in order to prevent sliding of spacer 4. The same can be the case for second protuberance 8b.

It is advantageous to provide for first portion 8a′ of first protuberance 8a and first portion 8b′ of second protuberance 8b to be facing first portion 4′ of spacer 4 in direction X. This embodiment is particularly advantageous as it prevents any movement in direction X, any movement in direction Y, and rotation of spacer 4 relatively to first substrate 1.

It is advantageous to provide for spacer 4 to comprise at least two different portions defining at least one salient area and preferably at least two salient areas. In the embodiment illustrated in FIGS. 2, 3 and 4, spacer 4 comprises at least three distinct portions defining two salient areas or more than two salient areas. It is particularly advantageous to provide for first portion 8a′/8b′ of first protuberance 8a and/or of second protuberance 8b to have a larger width than the respective second portions 8a″/8b″ of the protuberance when the protuberances are made from brazing material. This larger width corresponds to a larger quantity of material thereby enabling risks of depletion of brazing material to be reduced. In advantageous manner, portions 8a′ and 8b′ are solely made from brazing material.

It is apparent that the width of spacer 4 and the width of protuberances 8a and 8b cannot be chosen such that spacer 4 is aligned without clearance with respect to the protuberances of first substrate 1, as this involves excessive constraints as regards the initial alignment of first substrate 1 with spacer 4.

The inventors observed that a spacing between spacer 4 and each of first and second protuberances 8a and 8b advantageously comprised in the 5 to 10 micron range makes for easier alignment and preservation of the alignment in time.

As indicated in the foregoing, first protuberance 8a and/or second protuberance 8b can comprise electrically conducting brazing materials. When electrically conducting wires 5a/5b are inserted hot in lateral grooves 3a/3b of the chip, the brazing material liquefies. As the brazing material is in liquid state, it wets electrically conducting wire 5a/5b by capillarity thereby increasing the contact surface between area 8a/8b and electrically conducting wire 5a/5b. Furthermore, by using a continuous protuberance 8a/8b with several portions having different widths instead of several physically dissociated protuberances, the electric and mechanical contact between electrically conducting wire 5a/5b and electric contact area 6a/6b is improved. The risks of depletion of brazing material in immediate proximity to electric contact area 6a/6b are greatly reduced.

As an alternative, the transformation anneal of the brazing material can be performed after the electrically conducting wires have been inserted in the lateral grooves.

After the annealing step of the brazing material and pumping of the latter by capillarity to secure the electrically conducting wire, a few traces of the initial shape of the protuberance may remain.

It is particularly advantageous to provide a brazing material that presents a higher melting temperature than the temperature used in the fixing step of the spacer with the first substrate.

This embodiment is particularly advantageous as, after the anneal used to insert electrically conducting wires 5a/5b, first and second protuberances 8a/8b used to prevent movement of spacer 4 have disappeared and have been transformed into first and second electrically conducting films respectively covering first and second electrically conducting wires 5a/5b.

As illustrated in FIG. 5, the volume initially occupied by a part of first protuberance 8a or of second protuberance 8b is left free. This new void can subsequently be filled by an encapsulation material 11, for example an adhesive which will enhance the adhesion between first substrate 1 and second substrate 2 and also with spacer 4 and electrically conducting wires 5a/5b. In advantageous manner, encapsulation material 11 is configured to fill the voids thereby enhancing the solidity of the chip. In a particular embodiment, encapsulation material 11 is a glue and advantageously a structural glue which can be a E505 glue marketed by EPO-TEK. It is also possible to use Parylene also called poly(p-xylylene) or a fusible glass.

As a variant, encapsulation material 11 can be a barrier material that is configured to prevent pollutants, for example water, from penetrating. In a particular embodiment, encapsulation material 11 is a glue and advantageously a protection glue that can be a TC420 glue marketed by POLYTEC. It is further possible to use an encapsulation material 11 performing both functions—adhesive and barrier. A TC420 glue marketed by POLYTEC can be used.

This embodiment is more advantageous than the one where the stop areas are not made from a brazing material. In the latter embodiment, the space between the electrically conducting wire and spacer 4 can in fact be small which considerably complicates the cleaning steps. Furthermore, it is difficult to insert an encapsulation material 11 that makes the chip more sensitive to external mechanical and/or chemical aggression.

Furthermore, by using first and second protuberances 8a/8b formed on first substrate 1, it is possible to use more varied chips and to add protuberances 8a/8b at a later stage. It is then possible to use chips having contact areas 6a/6b placed at different locations in groove 3a/3b and to form protuberances 8a and 8b afterwards so as to adjust the chip to spacer 4 and second substrate 2. It is possible to adjust the shape of the protuberances and the shape of the spacers to the type of chip, i.e. at least to the shape of the first substrate and to the position of the electric contacts on the main surface.

In another embodiment, first portions 8a′ and 8b′ of the protuberances are offset in direction Y towards the periphery of the first substrate instead of in the centre of the chip. This offset makes it possible for example to form L-shaped protuberances, for example on at least two opposite corners of the first substrate. These two protuberances form stops limiting movement of the spacer 4 in directions X and Y. This embodiment is advantageous as it enables a spacer to be used having a cross-section that is easier to achieve in the plane containing directions X and Y. For example purposes, the spacer has a rectangular cross-section, but a square cross-section can also be used. The spacer can be devoid of any salient area in directions X and/or Y while being blocked by the protuberances.

The same second substrate can be used on two consecutive first substrates having different integrated circuits provided that the dimensions of the chips are identical. The shape of the first and second protuberances will enable the first substrate to be adjusted to the second substrate.

Placing of second substrate 2 on first substrate 1 with the required alignment level can be achieved in industrial manner by means of bond aligners marketed by Suss MicroTec and EVG.

In a particular embodiment, spacer 4 is formed inside second substrate 2 by ion etching, preferentially by Reactive Ion Etching and more preferentially by Deep

Reactive Ion Etching.

The substrate is etched so as to form a spacer 4 presenting a height comprised between 100 microns and 200 microns. The height of spacer 4 corresponds to the height of the salient part compared with the rest of the second substrate. The height of spacer 4 is defined in accordance with the diameter of electrically conducting wires 5a/5b.

In advantageous manner, the length of spacer 4 is about a few hundred microns, for example between 100 microns and 1 millimetre. The width of spacer 4 is advantageously about a few tens of microns, for example between 10 microns and 100 microns.

Depending on the embodiments, protuberances 8a/8b formed on first substrate 1 are made by electrolytic growth or by screen printing. Other techniques are also available but are less practical from an industrial point of view. It is also possible to provide for a part of the protuberances to be formed by electrolytic growth and another part of the protuberances to be formed by another technique, for example by screen printing.

In advantageous manner, protuberances 8a/8b are salient from surface 1b of first substrate 1 by a height comprised between a few microns and a few hundred microns. For example purposes, the height of the protuberances is comprised between 2 microns and 500 microns.

The width of protuberance 8a/8b is advantageously a few tens of microns, for example between 10 microns and 100 microns.

The chips as they have been described can be integrated in clothing to form intelligent fabrics on account of their small size.

1-16. (canceled)

17. Method for fabricating an electronic device comprising successively:
providing a first stack comprising:
a first substrate comprising at least one main surface provided with a first electric contact area and a first protuberance arranged to form a stop,
a second substrate provided with a salient spacer,
assembling the first substrate with the second substrate so as to define a first lateral groove bounded by the first substrate, the second substrate and the salient spacer, the first electric contact area being located one a sidewall of the first lateral groove,
fixing the first substrate with the second substrate, the first protuberance limiting movement of the salient spacer relatively to the first substrate in at least a first direction passing via the first lateral groove and the salient spacer and limiting movement of the salient spacer relatively to the first substrate in a second direction parallel to a longitudinal axis of the first lateral groove and perpendicular to the at least first direction,
eliminating partially the first protuberance by means of an annealing step at a higher temperature than a melting temperature of a material forming the first protuberance.

18. Method for fabricating according to claim 17, wherein the first substrate further comprises a second electric contact area on said at least one main surface, the second electric contact area being distinct from the first electric contact area and wherein when assembling the first substrate with the second substrate, the first substrate and the second substrate are arranged to define a second lateral groove with the second electric contact area located on a sidewall of the second lateral groove, the first substrate, the second substrate and the salient spacer defining the second lateral groove being, and wherein the second lateral groove being separated from the first lateral groove by the salient spacer.

19. Method for fabricating according to claim 17, comprising fixing the salient spacer to the second substrate before assembling the first substrate with the second substrate.

20. Method for fabricating according to claim 17, wherein fixing the first substrate with the second substrate is performed by fixing the salient spacer with the first substrate by bonding, melting of a fusible material, molecular sealing or anodic sealing of the salient spacer with the first substrate.

21. Method for fabricating according to claim 17, wherein fixing the first substrate with the second substrate is performed by fixing the salient spacer with the first substrate, the fixing step being performed by applying a pressure stress between the first substrate and the second substrate.

22. Method for fabricating according to claim 17, wherein fixing the first substrate with the second substrate is performed by fixing the salient spacer with the first substrate, the fixing step being performed by means of a heat treatment.

23. Method for fabricating according to claim 17, wherein the first protuberance is electrically conducting for forming first electrically conducting protuberance and wherein the first electrically conducting protuberance is connected to the first electric contact area, the first electrically conducting protuberance being configured to prevent movement of the salient spacer at least in the at least first direction.

24. Method for fabricating according to claim 17, wherein the first protuberance defines at least one stop for the salient spacer in the at least first direction and the salient spacer comprises a first sidewall defining a first salient area in the first direction, the at least one stop collaborating with the first salient area to prevent movement of the salient spacer in the second direction.

25. Method for fabricating according to claim 18, wherein the first substrate comprises at least a second electrically conducting protuberance connected to the second electric contact area, the second electrically conducting protuberance being configured to prevent movement of the salient spacer at least in the first direction.

26. Method for fabricating according to claim 25, wherein the second electrically conducting protuberance defines at least one stop in the first direction and the salient spacer comprises a second sidewall opposite the first sidewall and defining a second salient area in the first direction, the second electrically conducting protuberance collaborating with the second salient area to block movement of the salient spacer in the second direction, the first and second electrically conducting protuberances blocking the salient spacer in the first direction and in the second direction in two opposite ways.

27. Method for fabricating according to claim 24, wherein the salient spacer comprises at least a first portion and a second portion, the first portion having a smaller width than the second portion, the width being defined along the first direction, the first and second portions being arranged consecutively in the second direction to define the first salient area.

28. Method for fabricating according to claim 27, wherein the salient spacer comprises at least a third portion having a larger width than the width of the first portion, the third portion being separated from the second portion by the first portion to define the second salient area.

29. Method for fabricating according to claim 27, wherein the first and second salient areas are separated by the first portion of the salient spacer.

30. Method for fabricating according to claim 17, wherein said at least first protuberance is made from a brazing material.

31. Method for fabricating according to claim 30, comprising inserting at least a first electrically conducting wire in the first lateral groove, the annealing step transforming a brazing material into a liquid material that at least partially covers the first electrically conducting wire by capillarity.

32. Electronic device comprising:
a first substrate comprising at least one main surface provided with at least one first electric contact area and at least one first protuberance,
a second substrate associated with a salient spacer, the salient spacer separating the first substrate and the second substrate to define a first lateral groove comprising the a first electric contact area, the first protuberance forming a stop and limiting movement of the salient spacer relatively to the first substrate in a first direction passing via the first lateral groove and the salient spacer,
a fixing layer connecting the salient spacer with the first substrate, the fixing layer being in a first state allowing movement of the salient spacer relatively to the first substrate and having a second state ensuring fixing of the salient spacer with the first substrate,
wherein the first protuberance is arranged to limit movement of the salient spacer relatively to the first substrate in a second direction perpendicular to the first direction, the second direction being parallel to a longitudinal axis of the first lateral groove, and wherein the first protuberance is formed from a material having a higher melting temperature than a transformation temperature of the fixing layer from the first state to the second state.
